(19) United States
(12) Patent Application Publication
(10) Pub. No.: US 2015/0275354 A1
(43) Pub. Date: Oct. 1, 2015

(54) VARIABLE DIAMETER NANOWIRES

(71) Applicants: Michael M. Oye, Oxnard, CA (US); Tam-Triet Ngo-Duc, Milpitas, CA (US); Jovi R. Gacusan, Sunnyvale, CA (US); Jan M. Heinemann, Mill Valley, CA (US); Meyya Meyyappan, Pacifica, CA (US); M.F. Mohan Sanghadasa, Huntsville, AL (US)

(72) Inventors: Michael M. Oye, Oxnard, CA (US); Tam-Triet Ngo-Duc, Milpitas, CA (US); Jovi R. Gacusan, Sunnyvale, CA (US); Jan M. Heinemann, Mill Valley, CA (US); Meyya Meyyappan, Pacifica, CA (US); M.F. Mohan Sanghadasa, Huntsville, AL (US)

(21) Appl. No.: 14/191,177

(22) Filed: Feb. 26, 2014

Related U.S. Application Data
(60) Provisional application No. 61/770,232, filed on Feb. 27, 2013.

(51) Int. Cl. C23C 16/40; C23C 14/22; C23C 16/06; C23C 16/44

(52) U.S. Cl. CPC C23C 16/40; C23C 16/44; C23C 14/22; C23C 16/06

(57) ABSTRACT

Methods for forming variable diameter nanowires enable a variety of applications. The top of the nanowires can provide a surface area that is suitable for the deposition of an electrode. In addition variable diameter nanowires can have a frequency response that is dependent upon the nanowire diameter. Nanowires having multiple diameters can have a broader bandwidth of resonance frequencies than a uniform diameter nanowire.

### CROSS-REFERENCE TO RELATED APPLICATIONS

This application claims the benefit of U.S. Provisional Patent Application No. 61/770,232 titled “Varying Nanowire Diameter for Top Electrode Contact Formation,” filed Feb. 27, 2013, incorporated herein by reference.

### STATEMENT REGARDING FEDERALLY SPONSORED RESEARCH OR DEVELOPMENT

The invention described herein was made by both government and nongovernment employees, whose contributions were done in the performance of work under a DARPA contract, and is subject to the provisions of Public Law 96-517 (35 U.S.C. 202). This invention was made with Government support under the following DARPA Contracts W-31P4Q-11-C-0230. The Government has certain rights in this invention.

### BACKGROUND OF THE INVENTION

1. Field of the Invention

The present invention relates to controlled growth of vertical nanowires on a substrate, and more specifically, it relates to controlled growth of vertical ZnO nanowires on copper substrate.

2. Description of Related Art

A challenge with integrating vertical nanowires to fabricate useful device structures is to make the top electrode contact, which involves sonic form of metal deposition. Usually, this has required a filling of the spaces in between the nanowires with a dielectric, with a possible back polishing step, to create a flat surface for metal deposition. It is desirable to provide methods for forming variable diameter nanowires such that the top of the nanowires can provide a surface area suitable for the deposition of an electrode.

Piezoelectric energy harvesting devices can be used. for converting mechanical energy to electrical energy. Nanostructured devices have a benefit of allowing for the potential of miniaturization with improved mechanical to electrical power conversion efficiencies. The response to the excitation of the nanowires is dependent on the natural frequency (or resonance frequency) of the nanowires. This natural frequency is dependent on both the material and geometry (dimensions and shape). Typical devices that employ nanowires for piezoelectric energy harvesting involve a geometry of the nanowires that is constant throughout a given nanowire (shape and geometrical lengths), and therefore only responding to a given resonance frequency. if the vibrating environment is not occurring at a frequency at which the device response (i.e. resonance frequency), then there will be no electrical power generated h the device. The piezoelectric energy harvesting nanowires will only generate power if the frequency that it is being vibrated at has a resonance frequency in that range. Since most vibrating environments are not vibrating at the resonance frequency of the nanowires, the devices are therefore resulting in sub-optimal configuration and inhibiting further deployment of the devices. It is desirable to provide nanowires with predetermined and varying diameters. By varying the geometry, the nanowires can respond to different resonance frequencies

### SUMMARY OF THE INVENTION

The invention provides methods for forming nanowires with segments of varying diameter. Such nanowires can be used in a variety of applications. For example, the top of the nanowires can provide a surface area that is suitable for the deposition of an electrode. In addition, nanowires with segments of varying diameters can cause a shift in the resonance frequency response that is dependent upon the nanowire diameter. Nanowires having multiple diameters can have a broader bandwidth of resonance frequencies than a uniform diameter nanowire. In order to carry this out it is helpful to understand several processes, generally including vertical ZnO nanowire growth on metal substrates and more specifically including controlled growth of vertical ZnO nanowires on a metal substrate such as copper. The controlled growth of nanowires on other substrates is within the scope of this invention. It is generally held that nanowires can gave a diameter of up to a micron and a length of up to a mm; however, the nanowires produced in the present invention are typically less than 100 nm in diameter and less than 200 nm in length, although nanowires of other dimensions can be produced by the methods taught herein.

### BRIEF DESCRIPTION OF THE DRAWINGS

The accompanying drawings, which are incorporated into and form a part of the disclosure, illustrate embodiments of the invention and, together with the description, serve to explain the principles of the invention.

FIG. 1 shows depth-profile Auger spectroscopy of an annealed FeCrAl metal alloy substrate.

FIG. 2A shows a TEM image of ZnO NWs at the base of the NW.

FIG. 2B shows a high resolution image TEM of the NW base showing a (0002) lattice spacing of 2.6 Å. The growth direction is also noted by the arrow.

FIG. 3 shows vertically aligned ZnO NWs grown on FeCrAl metal alloy substrates at 1:1200, O₂:Ar flow for 30 min.

FIG. 4 shows polycrystal oriented ZnO NWs grown on FeCrAl meta alloy substrates at 6:1.200, O2:Ar flow for 5 min. The inset shows a zoomed-in image.

FIG. 5 shows Raman spectra of ZnO nanowires grown on FeCrAl substrate using 514.5 nm excitation.

FIG. 6A shows a SEM image of vertical ZnO NW with varying diameter as a function of relative oxygen concentration versus growth time.

FIG. 6B shows NWs shown on a larger scale on the Cu substrate.

FIG. 7A shows two segment pairs involving narrow to wide growth.

FIG. 7B shows two segment pairs involving wide to narrow growth.

FIG. 7C shows NWs on a larger scale on the Cu substrate.

FIG. 7D shows “narrow-wide” and “wide-narrow” segment pairs, respectively.

FIGS. 8A-8C show prior art process steps to form an electrode on a nanowire structure.

FIGS. 9A and 9B illustrate general process steps of the present invention to form an electrode on a nanowire structure.

FIG. 10 is a plot showing frequency response as a function of nanowire thickness.

FIG. 11 shows example nanowire geometries that have different resonance frequencies.

FIG. 12 shows nanowire geometries that vary across a device.

FIG. 13 shows an example of an extended bandwidth or frequency response that can be produced with a variable thickness nanowire.

FIG. 14 shows an example nanowire having a variable thickness to enable a variable frequency response.

### DETAILED DESCRIPTION OF THE INVENTION

### Vertical ZnO Nanowire Growth on Metal Substrates

Vertical growth of ZnO nanowires (NWs) is usually achieved on lattice-matched substrates such as ZnO or sapphire using various vapor transport techniques. Accomplishing this on silicon substrates requires thick ZnO buffer layers. Here we demonstrate growth of vertical ZnO nanowires on FeCrAl substrates. The pre-annealing prior to growth appears to preferentially segregate Al and O to the surface, thus leading to a self-forming, thin pseudo-buffer layer, which then results in vertical nanowire growth as on sapphire substrates. Metal substrates are more suitable and cheaper than others for applications in piezoelectric devices, and thin self-forming layers can also reduce interfacial resistance to electrical and thermal conduction.

### Introduction

Zinc oxide (ZnO) has attracted attention for many potential device applications due to its direct wide band gap (3.37 eV) and high exciton binding energy (60 meV) at room temperature. ZnO nanowires have been one of the most investigated among all the inorganic nanowires and have been explored for applications in solar cells, photo-catalysts, chemical and biological sensors, thermoelectric and piezoelectric devices. Energy scavenging via the piezoelectric mechanism allows generation of a small amount of power from various sources of vibration such as walking/jogging, heartbeat, etc. ZnO nanowires have been thought to be ideal for this application since it is semiconducting and piezoelectric, ideal for electromechanical transducers. There is a strong directional dependence of the ZnO NW properties that warrants consideration in developing functional piezoelectric devices. While several device configurations exist, a vertical array of ZnO NWs is preferred for the ease of device fabrication and also for embedding in a matrix of epoxy or polymer. However, the orientation of as-grown ZnO NWs can vary from being well aligned to randomly oriented, which depends mostly on the synthesis technique and the choice of substrate.

Common ZnO NW synthesis techniques involve either hydrothermal, vacuum plasma synthesis, or vapor-phase transport, with the latter subdivided into vapor-liquid-solid (VLS) and vapor-solid (VS) growth approaches. All methods, including both VLS and VS techniques, have been used to demonstrate vertical ZnO NWs on the surface of a substrate. However, VLS typically requires higher growth temperatures to reach the eutectic temperature of the metal catalyst at ˜800-900° C. for the common Au catalyst, when compared to ˜450-550° C. for the VS synthesis. Moreover, the use of Au or any other catalysts such as Ni, Fe, Sn, Pt, etc., using the VLS method, may leave behind unreacted impurities on the substrate surface that can affect the device performance. The choice of substrate may also affect the orientation of the ZnO NWs. Commonly used substrates include ZnO, sapphire and Si, and directional growth of ZnO NWs is typically achieved using either ZnO or sapphire substrates due to the epitaxial lattice matching with the substrate. Si has been investigated as a substrate due to its lower cost compared to ZnO and sapphire, however the lattice matching between ZnO and Si is not as good compared to sapphire or ZnO. Furthermore, ZnO NWs on Si substrates typically are grown on the native silicon oxide since growth of ZnO inherently involves an oxygen precursor; the oxygen therefore oxidizes the silicon, and the ZnO NWS consequently grow on a thin layer of SiO₂ instead of directly on the Si itself. As a result, there have been many reports of randomly oriented ZnO NW synthesis on Si substrates but well-aligned vertical growth of ZnO NWs on Si substrates has also been reported using buffer layers that range from ˜30 nm up to a micron in thickness. The buffer layers are typically formed by either depositing Zn prior to NW growth or initially forming a ZnO layer onto which the ZnO NW grows. These buffer lavers have been proven to be critical for achieving vertical alignment when lattice matching between the ZnO NW and substrate is nonexistent. It would be preferable to minimize the thickness of this buffer layer in vertically aligned ZnO nanowires to potentially improve the electrical and thermal interface between the NWs and the substrate.

A final aspect involving device integration of vertically aligned ZnO NWs for thermoelectric and piezoelectric nanodevices is the electrical and thermal conductivity of the substrate. While semiconductor-based substrates such as Si, sapphire, and ZnO can be doped to drastically improve their electronic properties, growth of vertically aligned ZnO NWs directly on metallic substrates is preferable for improved electrical and thermal conduction, which, in turn, could improve device performance by incorporating the substrate as one of the electrodes. The integration of metal substrates for vertically oriented ZnO NWs has not been reported much to date with the exception of Zn foils, and here we report growth on a FeCrAl metal alloy substrate. An annealing process is used to form a pseudo-buffer layer of a sapphire-like aluminum oxide layer that allows direct vertical growth of ZnO NWs. This self-forming pseudo-buffer layer is relatively thin compared to conventional ZnO buffer layers (30 nm-1 μm) arising from pre-deposited ZnO, thus facilitating improved interface properties. The potential for atomically thin buffer layers could further reduce interfacial thermal and electrical resistance in future nanodevices.

### Experimental Work

The growth of ZnO nanowires was carried out in a 2 cm inner diameter quartz tube furnace at 550° C. for a duration of either 5 or 30 min. A 1 cm² size FeCrAl metal alloy substrate (purchased from Goodfellow Corporation, Oakdale, Pa.) with atomic compositions of 76% Fe, 21% Cr, and 3% Al was used to grow the nanowires. Growth was also carried out on plane sapphire and silicon substrates for the purpose of comparison. The FeCrAl metal alloy is commonly used as a high temperature alloy for furnace temperatures as high as 1500° C. The FeCrAl substrate was annealed in an ambient atmosphere comprising a 1:2 ratio of H₂:Ar (gas purities of 99.999%) for 30 min at 450° C. prior to growth. After annealing, the FeCrAl substrate was placed on a boat that contained the Zn powder (99.999%) precursor and loaded into the quartz tube furnace. Ar gas was used to first purge the tube prior to the temperature ramp to 550° C. and upon reaching the target temperature, an argon gas flow of 1200 standard cubic centimeters per minute (sccm) was used with either 1 or 6 sccm of O₂. The as-grown ZnO NWs were characterized with a Hitachi S4800 scanning electron microscope (SEM), Hitachi H-9500 transmission electron microscopy (TEM), energy-dispersive x-ray spectroscopy (EDS), Raman spectroscopy with a 514.5 nm excitation source, and Auger depth-profiling analysis.

### Results and Discussion

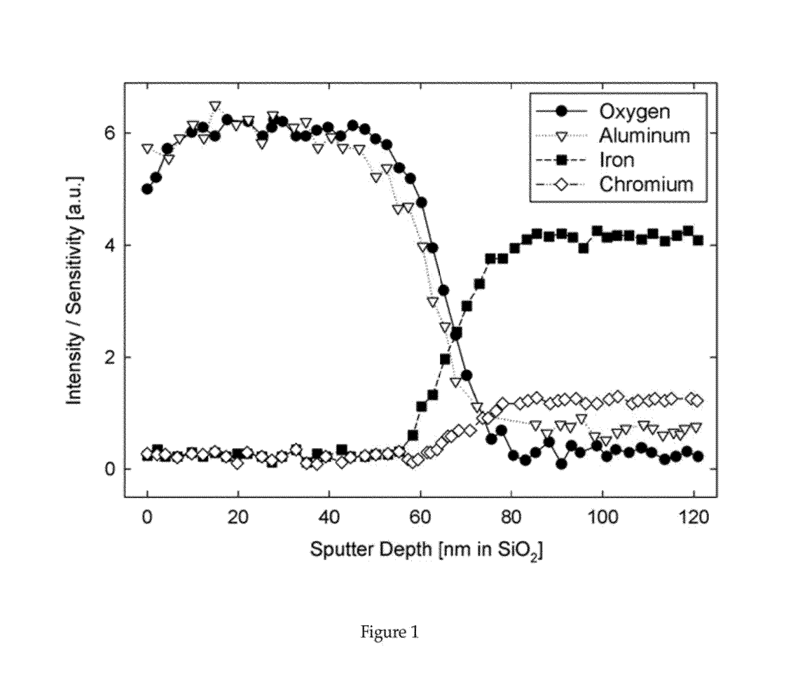

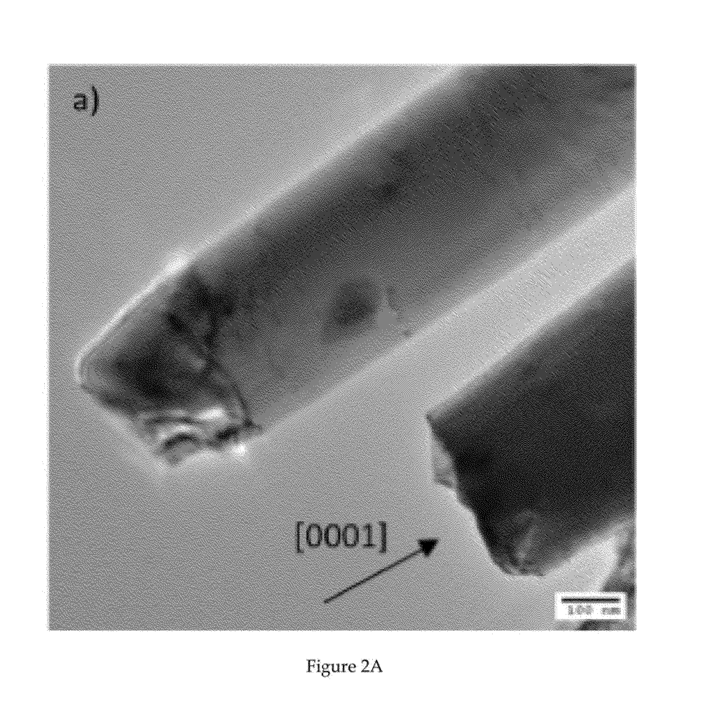

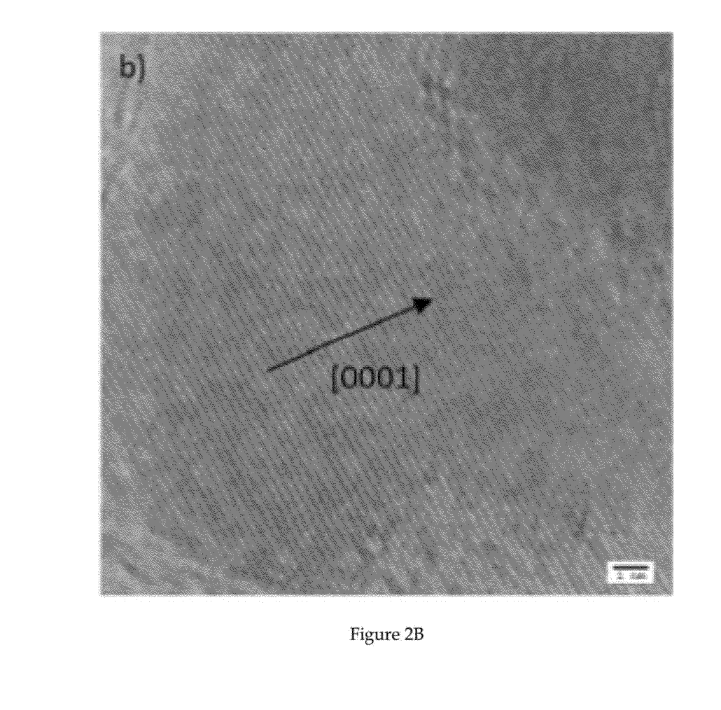

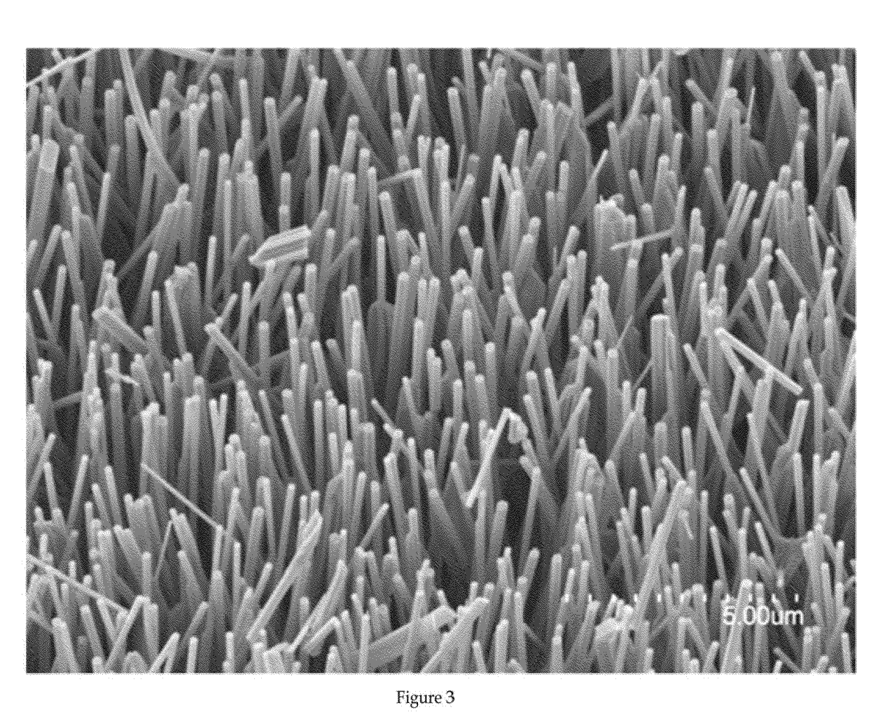

Depth-profiling Auger analysis on the FeCrAl metal alloy substrates was used to determine the composition of the Fe, Cr, Al, and O as a function of depth from the substrate surface. FIG. 1 shows the concentration as a function of sputter depth calibrated to SiO₂. The sputter ratio of Al₂O₃/SiO₂ is ˜0.5 and, therefore, the aluminum oxide thickness on the FeCrAl is estimated to be approximately ˜25 nm thick. Results from earlier work have involved a depth-profiling Auger analysis with a lower hydrogen flow rate, which led to a less reducing environment, and hence a lower proportion of oxygen on the surface of the metal. Further optimization of the annealing conditions in the future could make this aluminum oxide surface layer even thinner. The substrate annealing, done prior to growth, resulted in a preferential segregation of the Al toward the surface to become rich in Al and O within ˜25 nm underneath the surface, thus leading to a surface that is sapphire-like in terms of chemical composition (Al and O). The exact stoichiometry or crystal structure (if any) is unknown at present as well as the cause for the preferential segregation of Al and O to the surface of the FeCrAl metal alloy substrate. One possibility is that the residual oxygen present in the annealing gas is preferentially binding to the Al at the surface instead of the Fe or Cr. This can be reasonably determined by comparing the free energy of oxide formation for Fe, Cr, and Al at 450° C. Al has the lowest free energy of oxide formation with −975 kJ, compared to Cr with −650 kJ and iron oxides >−500 kJ. Therefore, oxygen can be expected to preferentially bind to Al due to a lower free energy of oxide formation versus Cr or Fe. As all three elements substitutionally interdiffuse within the FeCrAl metal alloy during annealing, residual oxygen in the furnace could therefore be preferentially keeping the Al near the substrate surface. In any case, a substrate with this layer is useful to grow vertically aligned ZnO NWs as in any sapphire substrates commonly used for this purpose. SEM analysis was used to characterize the nucleation and growth during the early stages (at 30, 60, 90, and 120 s) to better understand the effect of the first ZnO nuclei formation. The ZnO nuclei were observed to form on top of the Zn layer that was initially deposited on the self-forming pseudo-buffer layer. TEM was used to further characterize the interface between the NWs and the self-forming pseudo-buffer layer. The ZnO NWs grown on the FeCrAl metal substrate were torn off from the substrate using a razor blade and transferred to a TEM grid. FIG. 2A shows the jagged-shaped end of the NWs where they were pulled if from the substrate and FIG. 2B shows a high resolution TEM image at the jagged-shaped NW base. The NW has a (0002) lattice spacing of 2.6 Å which is consistent with ZnO growth along the preferred [0001] direction of the ZnO NW. A top-down oblique view of the ZnO NWs is shown in FIG. 3 at a 30° angle with respect to normal. The energy-dispersive spectroscopy (EDS) from the SEM confirms the presence of Zn and O with compositions of 55% and 45%, respectively. This is consistent with previous reports of comparable compositions, attributed to an elevated oxygen vacancy concentration due to the inherent defects that form during NW synthesis. However, the stoichiometric discrepancy is also likely to be due to a measurement artifact, since penetration depth and interaction volume of the electrons from the SEM are on the order of microns and EDS calibrations were done with bulk standards.

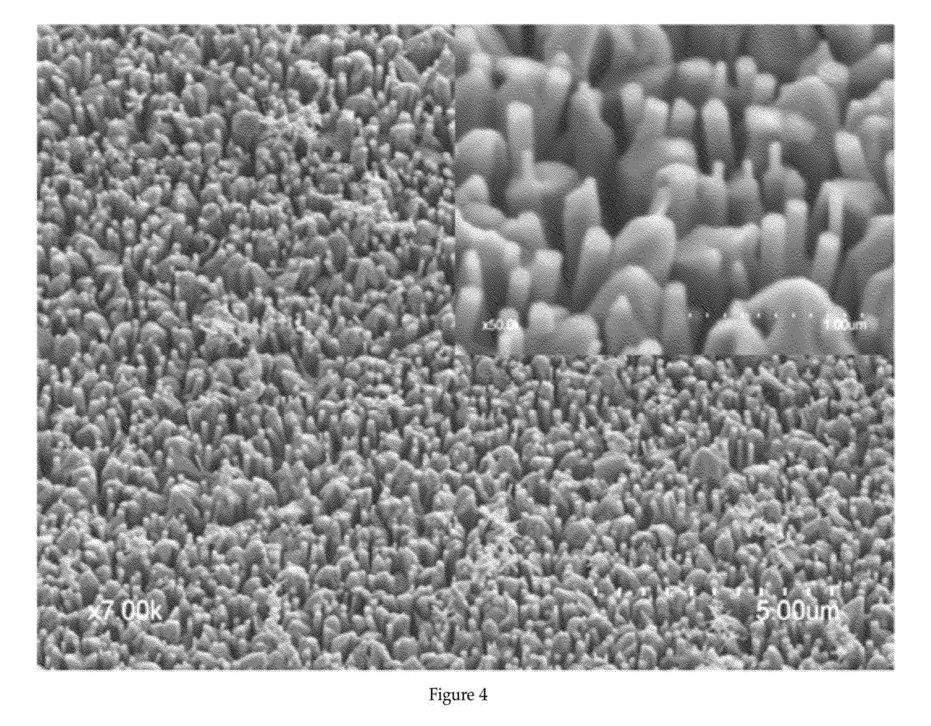

The NWs shown in FIG. 3 are mostly vertically oriented on the metal substrate with lengths of ˜10 μm and diameters of about a few 100s of nanometers. The lengths and diameters are strongly dependent on the oxygen concentration in the O₂/Ar feedstock. The NWs shown in FIG. 3 were grown at 1 sccm O₂ and 1200 sccm Ar for 30 min, which were found to be the optimal conditions here. As a comparison, FIG. 4 shows a SEM image of ZnO also grown on the same annealed FeCrAl metal substrate, but under different O₂/Ar gas feedstock conditions of 6 sccm O₂/1200 sccm Ar and for only 5 min. The higher magnification inset of FIG. 4 shows a region in which ZnO clusters of different sizes as well as larger polycrystals have formed. For comparison, we also grew another sample for 30 in under the same gas flow conditions and it exhibited no visible change compared to the 5 min growth at this O₂/Ar ratio, thus suggesting that the background ZnO polycrystal formation had been formed due to the overabundance of oxygen in the feedstock and irreversibly rendered the ZnO layer unsuitable for growing any king vertically aligned ZnO NWs with high aspect ratio.

The oxygen concentration in the feedstock is expected to affect the length and diameter of the NWs because of the interplay between the arrival rates of Zn and O species, surface diffusion, and incorporation into the NW. Since liquid droplets were not observed at the tip of the NWs, the effect of Zn surface mobility will then be a significant consideration. A larger oxygen concentration will increase the oxidation rate of the Zn; once oxidized, the Zn species will not be as mobile on the surface. As a result, a thicker ZnO blanket layer is expected, along with NWs with larger diameters. In the extreme case, where the oxygen concentration becomes very large, we have observed that a blanket layer of polycrystalline ZnO dusters forms on the surface similar to what is shown in FIG. 4 and limits the growth of the vertically aligned ZnO NWs. On the other hand, if the oxygen concentrations were small such that the surface mobility of the Zn species could dominate, then the Zn will have enough opportunity to move on the surface and form a regular array of uniformly sized, smaller diameter NW (as seen in FIG. 3). The extreme case of lack of oxygen during growth will not result in any ZnO NW growth whatsoever. Similar effects have been reported in In₂O₃ system as well where nanowire formation, though random, occurs only for an oxygen ratio of less than 0.2% in argon and transitions to nanoflakes or thin films at higher oxygen fractions.

The oxygen concentration in the source gas is critical to the length and vertical growth of ZnO NW, but so too is the selection of the appropriate substrate. For Si substrates where a ZnO buffer layer is needed for vertical NW alignment, the growth recipe must be adjusted to accommodate the formation of a ZnO buffer layer suitable for NW growth. The epitaxial substrates such as ZnO and sapphire do not require significant lattice matching to facilitate vertical ZnO NWs. Therefore, it would be expected that the same growth recipe used here for FeCrAl metal alloy substrates should also result in vertical NW growths on sapphire. This was indeed confirmed by growing ZnO NWs on sapphire substrates under identical growth conditions as in FIG. 3 for the FeCrAl metal substrate. However, identical growth conditions did not lead to vertical NW growth on silicon substrates, as expected, since these growth conditions did not allow the formation of the required ZnO buffer layer on the Si substrate which is necessary to achieve high aspect ratio NW with vertical alignment.

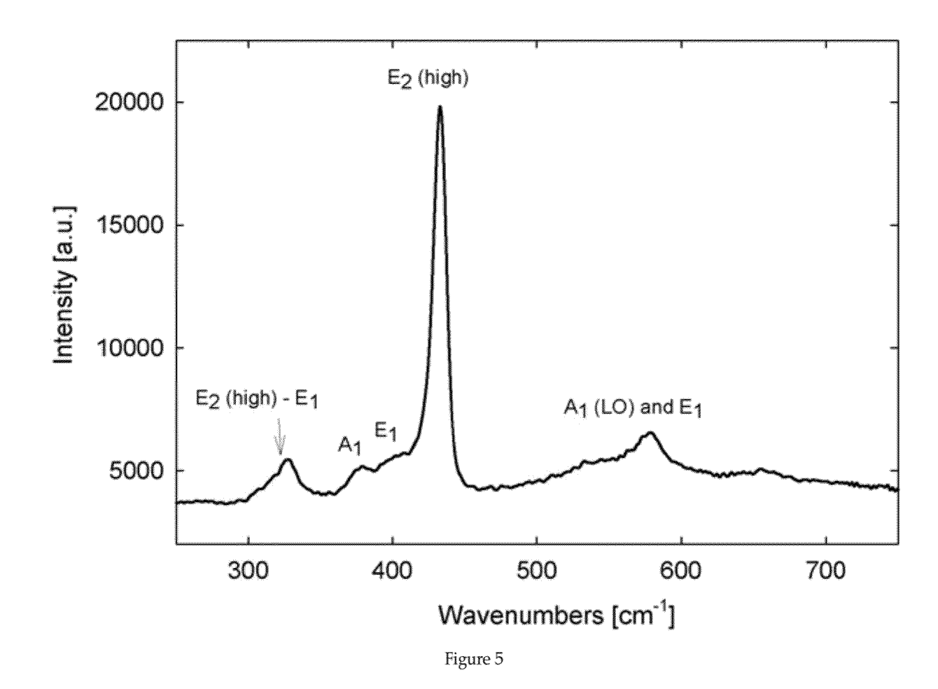

Raman spectroscopy was used to provide additional information on the properties of the synthesized ZnO NWs. FIG. 5 shows Raman spectra consisting of several bands that correspond to Raman-active phonon nodes of wurtzite ZnO nanowires with C6V symmetry. The Raman-active phonons predicted by group theory are A₁+2B₁+E₁+2E₂. The B₁ (low) and B₁ (high) modes are normally silent, A₁, E₁, and E₂ are Raman active and A₁ and E₁ are also infrared active. The E₂ is a non-polar phonon mode with two frequencies of E₂ (high) corresponding to oxygen atoms and E₂ (low) corresponding to Zn. Both the A₁ and E₁ are polar phonon modes, thus they each experience frequencies for transverse-optical (TO) and longitudinal-optical (LO) phonons. The dominant line at 438 cm⁻¹ corresponds to the E₂ (high) vibration mode which is a characteristic band of wurtzite phase with orientation in the c-axis. The spectrum also shows the forbidden mode at 333 cm⁻¹ frequency of second order described by E₂ (high)−E₁ (low) phonons. The peaks at 580 cm⁻¹ correspond to the A₁ (LO) and E₁ (LO) vibration modes which indicate the crystal disorder if the peaks are shifted to a different frequency. The peak at 580 cm⁻¹ is a combination of the two modes, thus very broad and enhanced by disorder though they remain at lower intensity due to more ordered wurtzite structures as seen in the peak at 438 cm⁻¹. The E1 (LO) mode is theoretically not allowed according to the Raman rules, however it can be visible if the incident light beam direction is not well defined with the axis of the nanostructure (c-axis). The appearance of E₁ (LO) also indicates oxygen deficiencies, which is consistent with our EDS data. The peaks at 380 and 415 cm⁻¹ correspond to A₁ (TO) and E₁ (TO) respectively. These peaks are usually present due to the structural or doping induced disorder in the ZnO substrate.

We have thus grown vertically aligned ZnO nanowires on FeCrAl metal substrates using a self-forming, thin pseudo-buffer layer. This buffer layer is formed by annealing the FeCrAl metal substrate prior to growth, which is a thin sapphire-like aluminum oxide surface that comprises only Al and O. Optimization of annealing conditions can lead to very thin layers helping to reduce interfacial resistance to electrical and thermal conduction. The amount of oxygen in the feedstock is also an important parameter in obtaining the desired nanostructures. This needs to be kept low enough to allow the dominance of Zn surface mobility in order to obtain a regular array of vertical NWs whereas excessive oxygen concentrations lead to polycrystalline ZnO clusters.

### Controlled Growth of Vertical ZnO Nanowires on Copper Substrate

We present an approach for diameter control of vertically aligned ZnO nanowires (NWs) grown directly on copper substrates. Vapor-solid growth was done at 550° C. with solid Zn precursor under Ar/O₂ flow, and the resulting nanowires with in situ-controllable diameters ranged between 50 to 500 nm. The nanowires were observed to elongate in tip growth and diameters were directly controlled by varying the oxygen concentration. Direct growth of vertical wires on metal substrates is expected to be useful to construct piezoelectric devices and applications involving sensors and detectors.

The synthesis of zinc oxide (ZnO) nanostructures has developed rapidly over the past decade. In particular, nanowires (NWs) have shown potential for use in several device applications due to their wide band gap (3.37 eV), high exciton binding energy (60 meV) at room temperature, and piezoelectric properties. ZnO NWs are useful in a wide range of devices, such as dye-sensitized solar cells, chemical and biological sensors, piezoelectric, and thermoelectric devices. The choice of substrate and the geometry of the nanostructure play a major role in development of the above devices. For example, NWs grown on metal substrates are preferable in some applications, compared semiconductor or insulating substrates, for improving electrical and thermal conduction through the substrate. In this regard, copper an ideal metal substrate for electrical and thermal conductance. The NW diameter and morphology can have a major impact in devices such as field effect transistors, chemical sensors and piezoelectronics.

We demonstrate direct growth of vertical ZnO nanowires on copper substrate and control of NW diameter during vapor-solid (VS) growth. VS growth does not involve an external catalyst, and the growth mechanism that determines the diameter of ZnO NWs is currently subject to controversy. When external catalyst and vapor-liquid-solid (VLS) mechanisms are involved, the molten catalyst particle causes variation of the contact area at the liquid-solid interface of NWs, which impacts the amount of Zn atoms supplied to the ZnO NW and therefore resulting in a variation of diameter during growth. In contrast, the mechanism for in situ diameter control with VS growth is not completely understood. Previous work has shown that there are mechanisms by which NWs grow: (1) screw-dislocation and (2) anisotropic growth mechanisms. In a screw-dislocation growth mechanism, the step edges formed from the dislocation on the (0001) surface provide energetically favorable sites where precursors react for NW growth. In anisotropic growth, NW growth progresses through preferential reactivity and binding of precursors along thermodynamically and kinetically favorable crystal facets to minimize surface energy. While both growth mechanisms contribute to VS growth, the experimental contributions from each are still not clear, especially with regards to NW diameter control during growth. Here, we demonstrate diameter control using VS growth of ZnO NWs on Cu substrates, and in the process help to elucidate an understanding of the growth mechanism.

ZnO NWs were grown in a 2.5 cm outer diameter quartz tube furnace at atmospheric pressure, as described above. Briefly, a boat filled with pure zinc powder (99.999% purity) is placed at the center of the tube. The Cu substrate is placed one centimeter from the source boat downstream from the gas flow. Prior to growth, the tube was purged with ultra high purity (UHP, 99.999%) argon at 1200 standard cubic centimeters per minute (sccm). Then the temperature was ramped (43.75° C./min) to 550° C. under 200 sccm of Ar and 1 sccm of UHP oxygen. Two gas flow conditions were used to control the oxygen concentration: (1) the flow of Ar was varied between 200 and 1200 sccm while keeping the oxygen flow rate constant at 1 sccm or (2) varying the oxygen flow rate (1-4 sccm), while keeping the Ar flow rate constant at 600 sccm. The sample was cooled to room temperature at a rate of 40° C./min at the end of a pre-specified growth period, prior to the removal of the sample. The NWs were characterized by scanning electron microscopy (SEM) with energy dispersive spectroscopy (EDS) and Raman spectroscopy. All SEM images in this work were taken at 30° with respect to substrate normal. EDS confirmed the presence of Zn and O species as well as the Cu substrate underneath the ZnO, and no other species were detected. Raman spectra (not shown here) of the as-grown ZnO NWs exhibited peaks at 333, 380, 415, 438, and 580 cm⁻¹, which correspond to the E₂ (high)−E₁, A₁, E₁, E₂ (high), and A₁ (LO)+E₁ peaks, respectively. The measured Raman peaks are in accordance with other ZnO work.

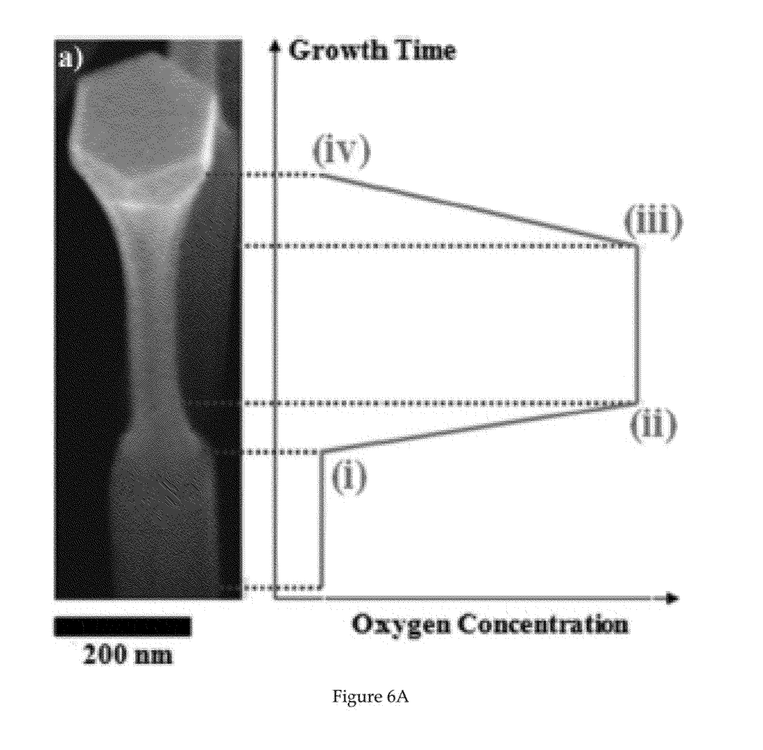

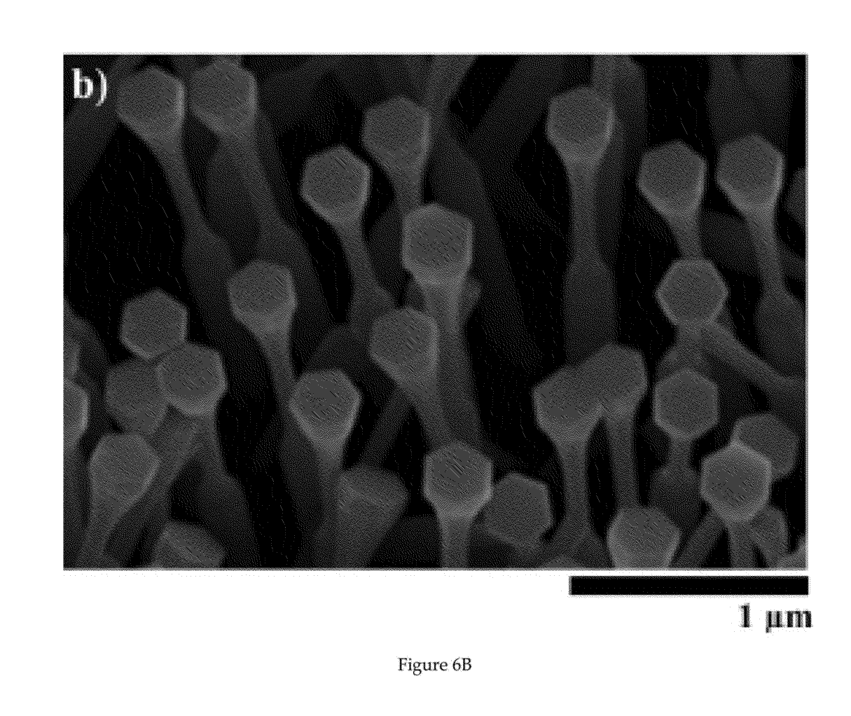

FIG. 6A shows a vertical ZnO NW grown to illustrate the effects of varying oxygen concentration. By increasing or decreasing oxygen concentration, NW diameter can be controlled at will during growth. For the case in FIG. 6A, oxygen concentration was changed by reducing Ar flow rate from 1200 to 200 sccm, while keeping constant the oxygen flow between stages (i) and (ii). Upon reaching equilibrium at (ii), the NW grows at a constant diameter until the concentration of oxygen is changed again at stage (iii), and subsequently, the NW diameter increases between stages (iii) and (iv). The hexagonal facets at the top of the NW are indicative of the c-plane (0001) surface and the resulting [0001] growth direction. FIG. 6B shows NWs shown on a larger scale on the Cu substrate.

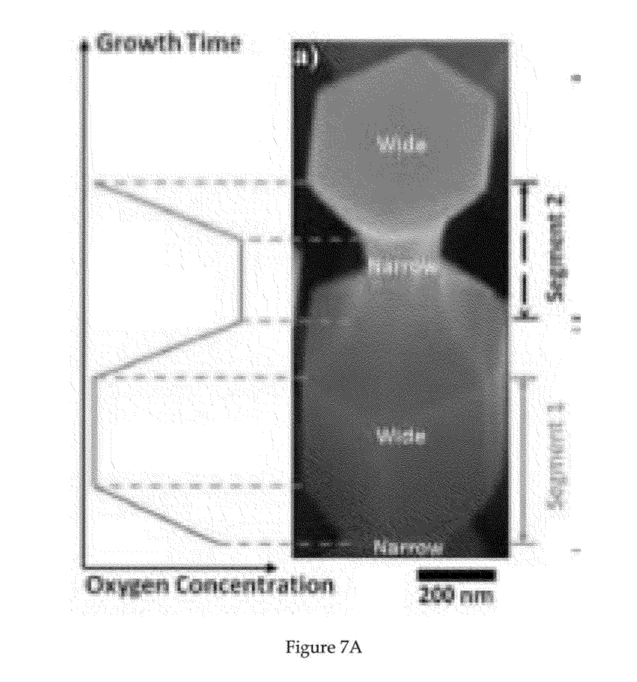

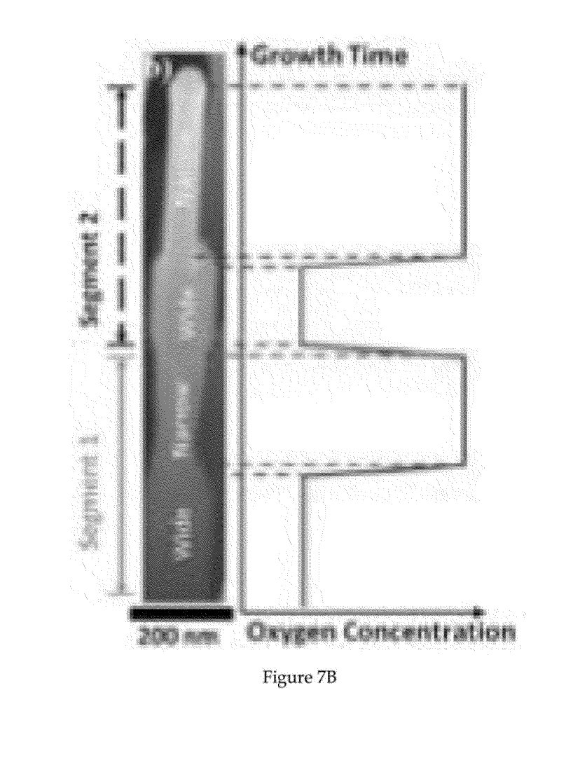

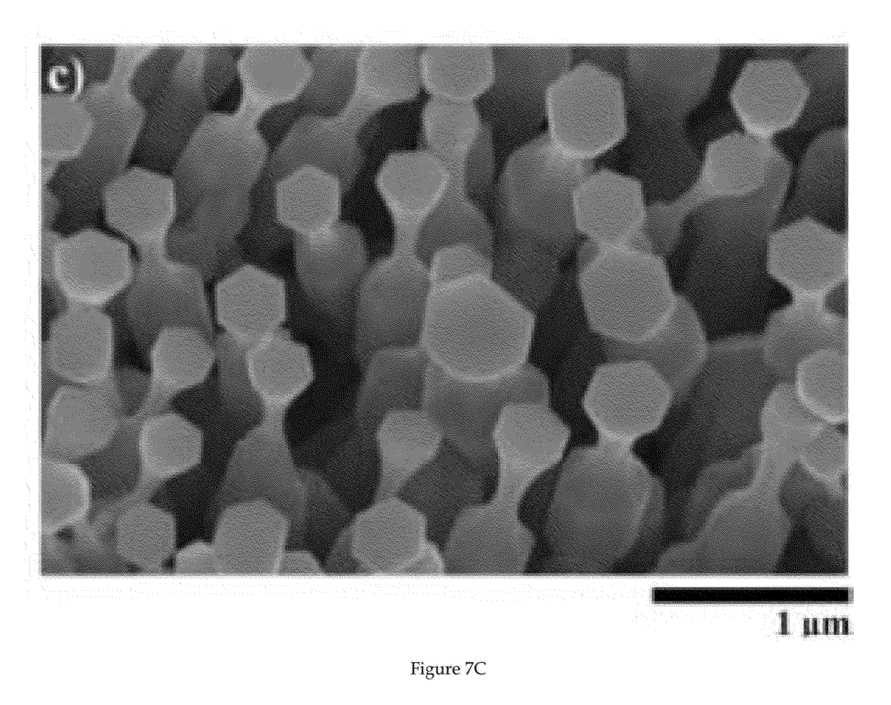

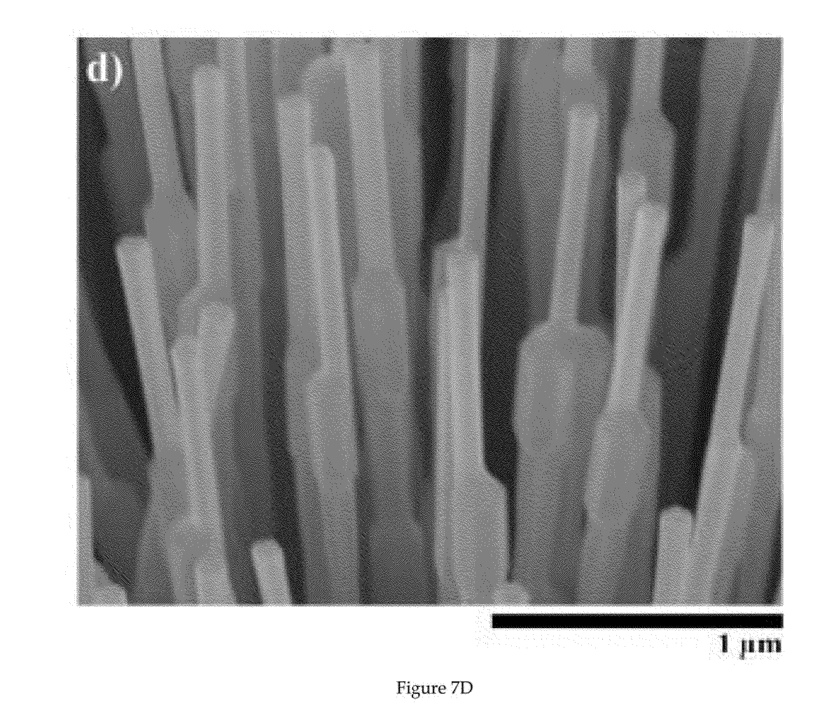

FIGS. 7A and 7B show vertical ZnO NWs grown with an added oxygen concentration variation step, which leads to two full segment pairs of varying “wide-narrow” or “narrow-wide” diameter configurations. In FIG. 7A, the NW was initially grown with a high oxygen concentration (thus resulting in a narrow diameter) and subsequently grown with a lower oxygen concentration leading to a larger diameter. This completed the first segment pair involving a “narrow-wide” configuration. In the second segment of the NW in FIG. 7A, the oxygen concentration is again increased, which leads to a narrower diameter, and then subsequently decreased again to result in a wider diameter. This created the second “narrow-wide” segment pair. The O concentration was varied by changing the Ar flow rate, while keeping O₂ flow rate constant. These steps were all done in situ and corroborate our direct control of NW diameter as a function of oxygen concentration.

Additionally, the length of the NWs was proportional to the growth time. As such, we changed growth time for various segment pairs and observed a correlation between growth time and length of each segment (not shown here). This was to further confirm NW growth was progressing at the tip. The determination of tip growth is important because of conflicting growth mechanisms reported in the literature for VS-grown NWs with varying diameters. By directly controlling MN diameter during growth in this work, we demonstrate that growth is progressing through the tip. To confirm that a larger diameter flat layer of ZnO is not forming during the conclusion of our growth, we show in FIG. 7B the termination of NW growth with a high oxygen concentration step. This led to a corresponding narrow diameter NW at the tip end.

In FIG. 7B, the Ar flow rate was kept constant and the O2 was varied. Again, two segment pairs were grown, but instead with opposite polarity linking two segment pairs of “wide-narrow” configuration The final growth step was the high oxygen concentration, which corresponds to the observed narrow diameter as the NW's tip. Moreover, there is no metal catalyst, such as Zn or Cu, on the flat tops of the NWs as observed from the SEM and there were no traces of any Cu contamination anywhere along the ZnO NW as measured by EDS, indicating that NWs were not grown via the VLS mechanism. Growths were also halted at various stages (not shown here) to determine whether any catalysts were present, but none were observed. In addition, low temperature growth regimes of this work (˜550° C.) favor VS growth, which do not involve formation of a molten catalyst as in VLS growth.

In contrast to some proposed mechanisms of the ZnO layer getting pushed up during growth, as with nanonails, FIGS. 6A through 7B confirm that growth is occurring at the tip. This means NWs only require an initial seed layer for nucleation to occur. This ZnOx seed layer forms during the temperature ramp up from room temperature to 550° C. Upon reaching a critical thickness, the NWs begin to nucleate and grow in the [0001] direction. This is because the highest surface energy plane of ZnO is (0001), when compared to other ZnO planes. Growth of this seed layer on metal substrates, such as Cu, is also demonstrated in this work. Once the ZnO NW growths are initiated from this seed layer on the Cu substrate, the subsequent diameter control of VS growth of ZnO NW is not expected to be only applicable to the growth on Cu substrates. Indeed, we have grown ZnO NWs on stainless steel previously without the aid of any catalysts.

In faster ramp rates during heating, we observed ZnO NW growth occurring in non-vertical orientations, where each group of micron-sized diameter regions on the Cu substrate had NWs pointing in the same direction within each respective region. We suspect that it was due to different grain orientations of the surface.

During ZnO NW growth, Zn atoms arrive on any surface with equal probability because growth occurs at atmospheric pressure. For atoms that stick, it becomes a mobile surface adatom until it either: (i) finds a step edge, such as the screw dislocation on the (0001) ZnO NW top surface where it gets incorporated during growth, (ii) desorbs off the surface, or (iii) the atom's motion is inhibited by the Ehrlich-Schwoebel (ES) barrier at the edge of the (0001) surface that would cause a buildup of Zn atoms on the outer edge of the (0001) surface. The NW diameter remains constant during growth when an equilibrium balance is achieved between these three factors. Variations in oxygen concentration due to changes in gas flow rate disrupt this equilibrium. Therefore, in the case of lower oxygen concentration, there are more available Zn surface adatoms that favors an equilibrium with larger NW diameters during growth. This is because more Zn atoms are available to diffuse over the edge before nucleation of the next atomic layer, as is observed with the varied and controlled diameters shown in FIGS. 6A through 7D. More specifically, FIG. 7C shows NWs on a larger scale on the Cu substrate and FIG. 7D shows “narrow-wide” and “wide-narrow” segment pairs, respectively.

The influence of O versus Zn atom arrival rates can be a factor in determining diameter control of NW in VLS growth. To better determine the effect of oxygen for VS growth, both oxygen concentration and absolute amount of oxygen were increased for the case in FIG. 7B. There were more abrupt interfaces that resulted between NW sections with the different diameters. This illustrates the distinction in the extent of surface migration between Zn and O adatoms. Since Zn has a sticking coefficient near unity, compared to ˜0.3 for oxygen, the O adatoms do not have as much opportunity to migrate on the surface compared to the Zn adatoms. As a result, the O is more prone to getting quickly incorporated into the NW during growth, thereby resulting in more abrupt interfaces.

We have thus demonstrated diameter control of VS-grown, vertically aligned ZnO NWs directly on bulk Cu substrates. The NW diameter was controlled in situ by varying oxygen concentration during growth. Higher oxygen concentrations led to relatively more narrow NW diameters and contributed to more abrupt in at the transition between sections with different NW diameters. The temperature ramp rate was also a factor influencing the vertical nature of ZnO NWs. Growth of vertical nanowires with controllable diameter on conductive substrates such as copper is expected to benefit construction of piezoelectric and other devices.

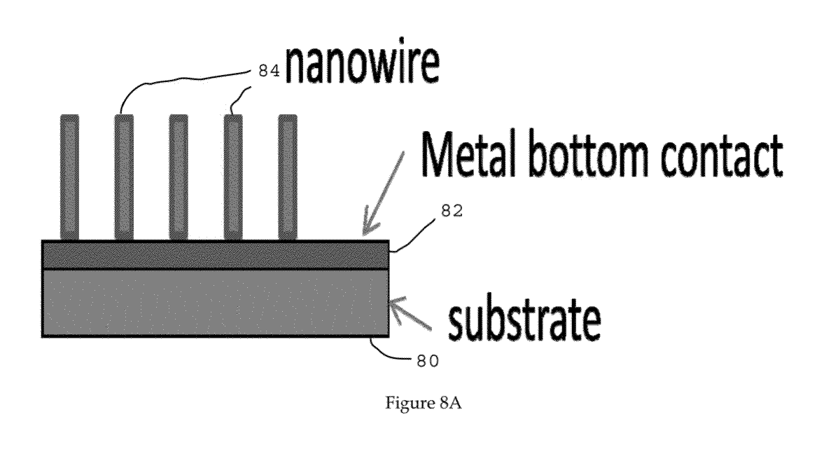

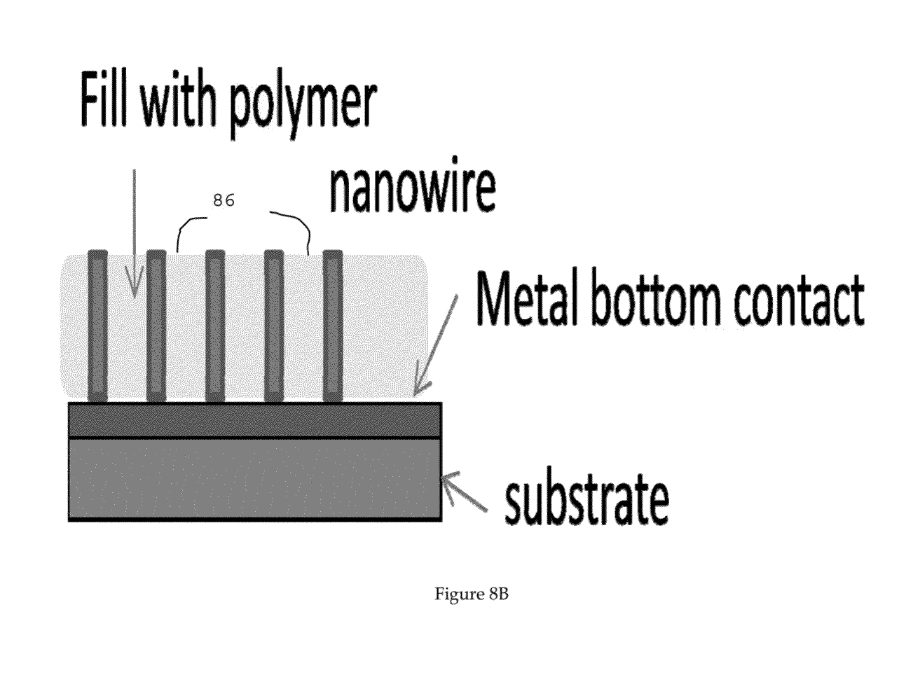

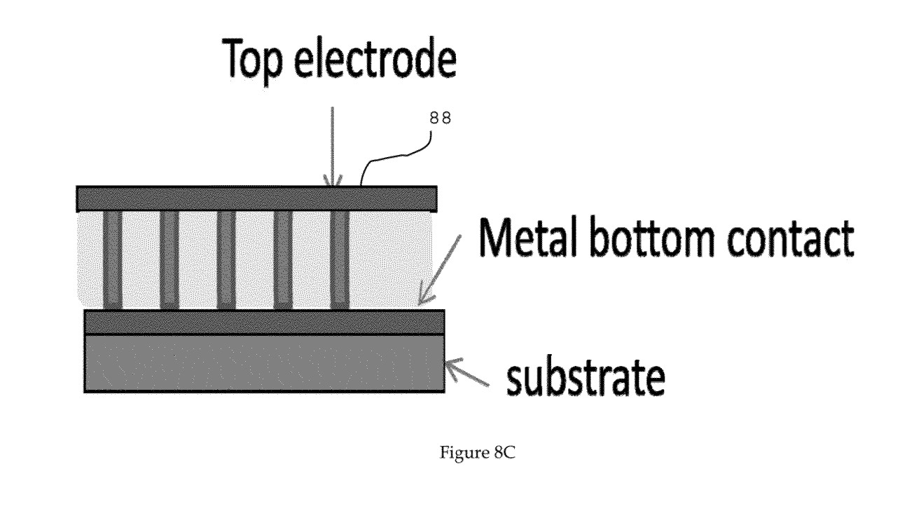

We now turn to a discussion of processes for varying the nanowire diameter to enable top electrode contact formation. To understand the invention, we first review a prior art method. FIGS. 8A-8C show prior art process steps to form an electrode on nanowire structure.

FIG. 8A shows a substrate 80 upon which a metal bottom contact 82 is deposited. Nanowires 84 are then grown on the metal bottom contract. As shown in FIG. 8B, the spaces between and surrounding the nanowires 84 are filled with a polymer 86. FIG. 8C shows the top electrode 88 formed on the plane formed at the top of the nanowire/polymer composite. It may be necessary to polish the top of the nanowire/polymer composite prior to the deposition of the top electrode.

Through the use of the methods described above for growing nanowires with diameters that are controllable, the tops of the nanowires can be formed in such a way that they present a flat surface upon which the electrode can be easily deposited, and thus, the filling process is not needed.

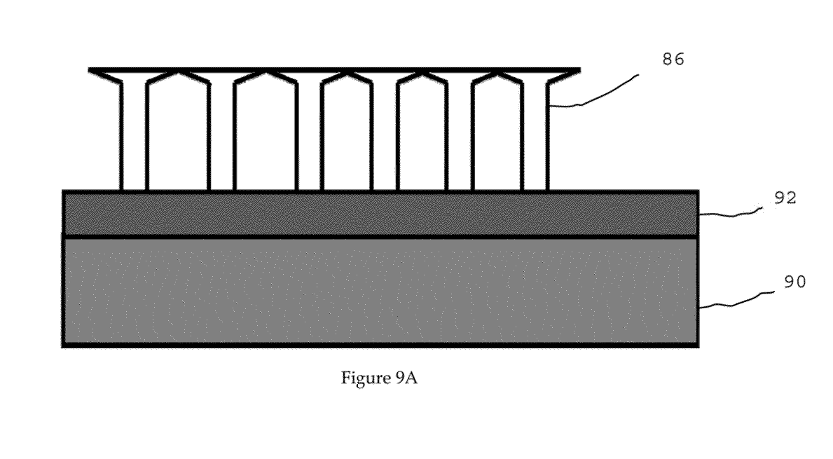

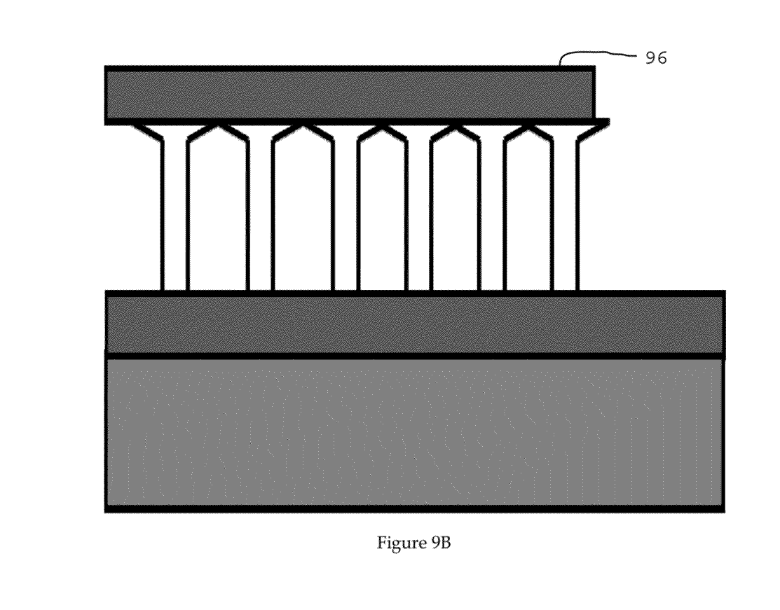

FIGS. 9A and 9B illustrate general process steps of the present invention to form an electrode on a nanowire structure. FIG. 9A shows a substrate 90 upon which a metal contact 92 has been deposited. As shown in FIG. 9A, nanowires 94 with wider tops are grown on the metal contact 92. FIG. 9B shows an electrode 96 that has been deposited onto the wider tops of the nanowires of FIG. 9A. Furthermore, an added advantage is that empty space in between the nanowires may allow further bending of the nanowires, thereby causing improved mechanical deformation leading to better device performance.

Piezoelectric energy harvesting devices can be used for converting mechanical energy to electrical energy. Nanostructured devices have a benefit of allowing for the potential of miniaturization with improved mechanical to electrical power conversion efficiencies. The response to the excitation of the nanowires is dependent on the natural frequency (or resonance frequency) of the nanowires. This natural frequency is dependent on both the material and geometry (dimensions and shape). Typical devices that employ nanowires for piezoelectric energy harvesting involve a geometry of the nanowires that is constant throughout a given nanowire (shape and geometrical lengths), and therefore only responds to a given resonance frequency. If the vibrating environment is not occurring at the frequency at which the device responds (i.e., the resonance frequency), then there will be no electrical power generated by the device. The piezoelectric energy harvesting nanowires will only generate power if the frequency that they are being vibrated at has a resonance frequency in that range. When a vibrating environment does not vibrate at the resonance frequency of the nanowires of a device, the device will have a sub-optimal configuration and its usefulness will be limited.

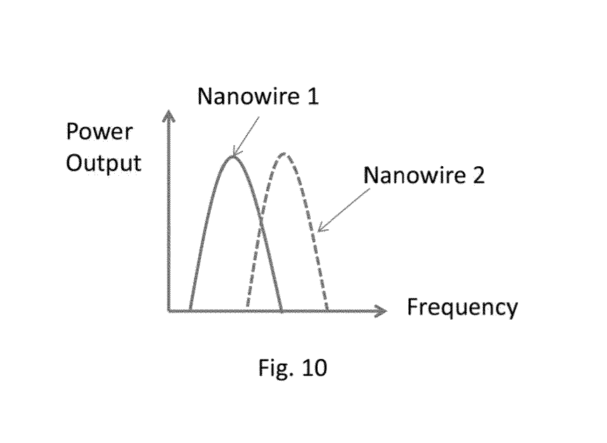

By varying the geometry, the nanowires can be made to respond to different resonance frequencies FIG. 10 is a plot showing frequency response as a function of nanowire thickness. By varying the O₂ concentration during growth, the geometries can be controlled such that the frequency response will vary on the same substrate. This enables devices that will respond to a wider bandwidth of frequencies.

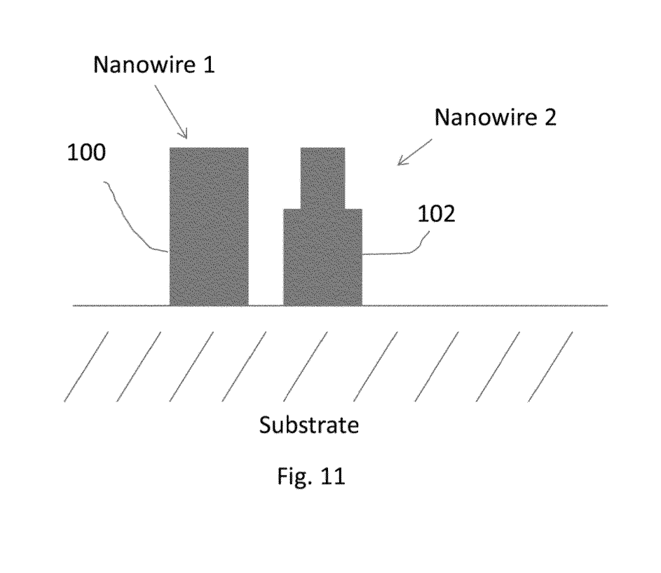

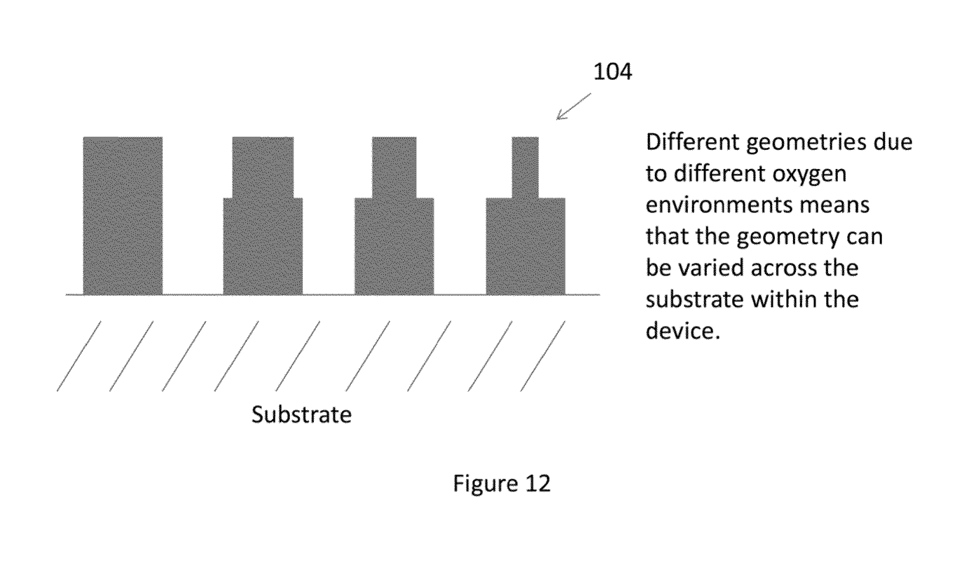

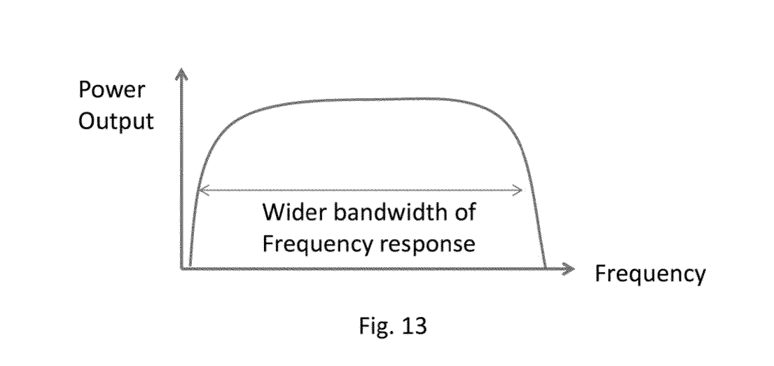

It is known that the resonance frequency of a beam is given by:

$$\sqrt[A]{\frac{El}{μ {L}^{4}}}$$

where A is constant, E is the Young's modulus, I is the area moment of inertia, μ is the mass per unit length and L is the length of the beam. The advantage of a variable diameter nanowire is that the Young's modulus for dimensions less than 100 nm is dependent on the geometry. Furthermore, the mass per unit length varies according to the diameter of the variable diameter nanowires. This change in the resonance frequency makes a nanowire responsive to a different excitation frequency, and having a substrate with different nanowire geometries can therefore increase bandwidth for the frequency response of nanostructured piezoelectric energy harvesting devices. FIG. 11 shows example nanowire geometries 100 and 102 that have different resonance frequencies. FIG. 12 shows nanowire geometries 104 that vary across a device. FIG. 13 shows an example of an extended bandwidth or frequency response that can be produced with a variable thickness nanowire.

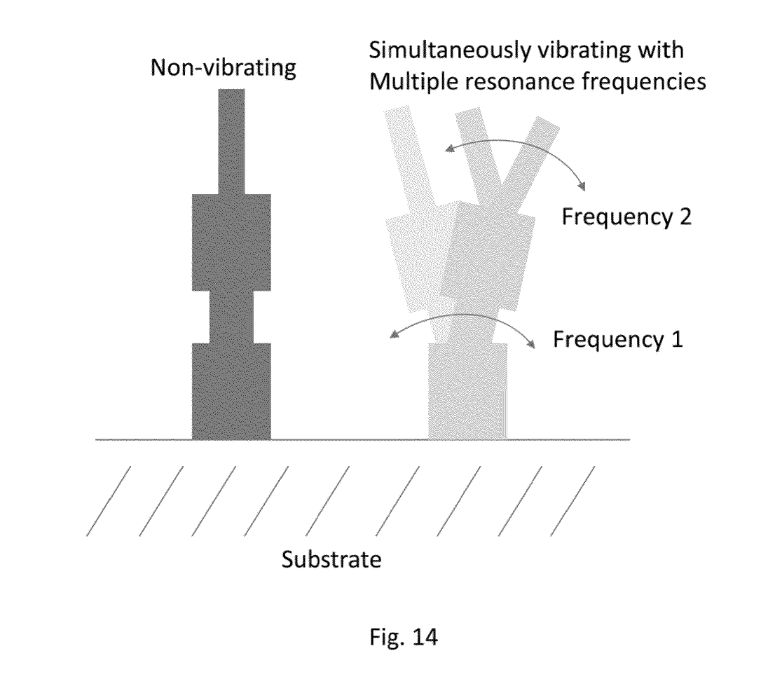

One method for producing a nanowire geometry that varies across a device is where flow rates of oxygen of 1 standard cubic centimeter per minute (sccm) are used, for an Ar flow rate of 1200 sccm. If the oxygen to argon flow rate ratio was too low, then the oxygen gets consumed in the front edge of the substrate and the diameters of the nanowires across the substrate would not be uniform. In another method, the diameters are controlled in such a way as to have multiple resonance frequencies from the same nanowire, similar to an antenna on a tall building vibrating at one frequency, while the building vibrates at another. FIG. 14 shows an example nanowire having a variable thickness to enable a variable frequency response.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

We claim:

1. A nanowire growth method, comprising:
providing an environment for containing a gas;
placing a first substrate in said environment;
introducing a first partial pressure of oxygen into said environment;
growing a first nanowire length on said first substrate;
introducing a second partial pressure of oxygen into said environment; and
growing a second nanowire length fixedly connected to the end of said first nanowire length, wherein said second nanowire length is grown in said second partial pressure of oxygen.

2. The method of claim 1, wherein said first substrate comprises a metal layer.

3. The method of claim 1, wherein said nanowire comprises metal oxide.

4. The method of claim 3, wherein said metal oxide comprises ZnO.

5. The method of claim 1, wherein said environment includes at least one other gas.

6. The method of claim 5, wherein said at least one other as comprises an inert gas.

7. The method of claim 5, wherein said at least one other gas is selected from the group consisting of Argon, Helium, Nitrogen, Neon, Krypton and Xenon.

8. The method of claim 1, wherein the diameter of said first nanowire length is different from the diameter of said second nanowire length.

9. The method of claim 1, wherein said metal layer is located on a second substrate.

10. The method of claim 1, further comprising terminating the growth of said nanowire, wherein said second partial pressure of oxygen is less than said first partial pressure of oxygen such that the diameter of said nanowire is increased at its termination point.

11. The method of step 10, wherein said nanowire comprises a plurality of nanowires, wherein said plurality of nanowires together form a planar area at their collective termination points.

12. The method of claim 11, further comprising depositing a metal layer on said planar area.

13. The method of claim 2, wherein said metal layer comprises a metal selected from the group consisting of copper, gold, silver, platinum, zinc, tin, indium, aluminum, titanium, nickel, alloys of iron-chromium-aluminum alloy and alloys of nickel-chromium alloy.

14. The method of claim 9, wherein said second substrate comprises a material selected from the group consisting of silicon, silicon oxide, glass, copper, gold, silver, platinum, zinc, tin, indium, aluminum, titanium, nickel, alloys of iron-chromium-aluminum alloy and alloys of nickel-chromium alloy.

15. The method of claim 9, wherein said second substrate comprises a metal.

16. The method of claim 1, wherein said nanowire is grown by a process selected from the group consisting of a chemical vapor deposition process and a physical vapor deposition process.

17. An apparatus, comprising:
a substrate; and
at least one nanowire fixedly attached to said substrate, wherein one or more nanowires of said at least one nanowire comprises at least two different diameters.

18. The apparatus of claim 17, wherein said one or more nanowires comprises a proximal end where said nanowire is fixedly attached to said substrate and wherein said one or more nanowires comprises a distal end opposite said proximal end, wherein said distal end comprises an end diameter that is larger than a first diameter between said proximal end and said distal end.

19. The apparatus of claim 18, further comprising a metal layer deposited on planar region form by a plurality of said distal ends.
